(19) United States
(12) Patent Application Publication
(10) Pub. No.: US 2026/0040741 A1
(43) Pub. Date: Feb. 5, 2026

(54) METHOD AND APPARATUS FOR TRANSFERRING ELECTRONIC DEVICES

(71) Applicant: EPISTAR CORPORATION, Hsinchu (TW)

(72) Inventors: Chang-Tai HSIAO, Hsinchu (TW); Cheng-Wei PENG, Hsinchu (TW)

(21) Appl. No.: 19/285,173

(22) Filed: Jul. 30, 2025

(30) Foreign Application Priority Data
Jul. 30, 2024 (TW) 113128218

(51) Int. Cl. H10H 29/03; H01L 21/683

(52) U.S. Cl. CPC H10H 29/03; H01L 21/6836; H01L 2221/68354; H01L 2221/68363; H01L 2221/68386

(57) ABSTRACT

Some embodiments of the present disclosure discloses a method for transferring electronic devices. The method includes providing an electronic device array structure, a providing carrier, and a plurality of second electronic devices arranged on the providing carrier. Wherein the electronic device array structure includes a carrier and a flawed group arranged on the carrier. The flawed group includes a plurality of first electronic devices and a vacancy. A patterned light is formed to irradiate the providing carrier by using the electronic device array structure.

### CROSS REFERENCE TO RELATED APPLICATION

This application claims the right of priority based on TW Application Serial No. 113128218, filed on Jul. 30, 2024, and the content of which is hereby incorporated by reference in its entirety.

### TECHNICAL FIELD

The present disclosure relates to a method for transferring electronic devices and an apparatus for transferring the same, and particularly to a mass transfer process for electronic devices and an apparatus for the mass transfer process.

### DESCRIPTION OF BACKGROUND ART

A light-emitting diode (LED) chip is an optoelectronic semiconductor device that has good characteristics such as low power consumption, low heat generation, long operational lifespan, shock resistance, small size, and fast response speed. Therefore, the LED chip is suitable for various lighting and display applications.

A micro-LED chip refers to a small-sized LED chip, with its side length on micron scale, used as sub-pixels in LED displays. For example, a 4K resolution LED display requires approximately 24 million micro-LED chips.

A technique for transferring millions or even tens of millions of micro-LED chips is referred to as a mass transfer process.

In the mass transfer process, one of the steps is to replace bad micro-LED chips. For example, if the production yield of micro-LED chips before transfer is 99.6%, a 4K resolution micro-LED display may require the replacement of approximately one hundred thousand bad micro-LED chips to obtain a micro-LED display with about 24 million specification-qualified micro-LED chips. How to replace bad micro-LED chips efficiently and cost-effectively is inevitably a challenge to be overcome in the mass transfer process.

### SUMMARY OF THE DISCLOSURE

One embodiment of the present disclosure provides a semiconductor device. The method includes providing an electronic device array structure, a providing carrier, and a plurality of second electronic devices arranged on the providing carrier, where the electronic device array structure includes a carrier and a flawed group arranged on the carrier, and the flawed group has a plurality of first electronic devices and a vacancy. The method further includes forming a patterned light to irradiate the providing carrier by using the electronic device array structure.

Another embodiment of the present disclosure further provides an apparatus for transferring electronic devices. The apparatus comprises a first holder, a light source, and a second holder. The first holder is configured to carry an electronic device array structure, where the electronic device array structure comprises a carrier and a flawed group arranged on the carrier, and the flawed group has a plurality of first electronic devices and a vacancy. The light source is arranged on the first holder and configured to generate a light, where the light is converted into a patterned light through the electronic device array structure. The second holder is arranged below the first holder and configured to support a providing carrier.

### BRIEF DESCRIPTION OF THE DRAWINGS

FIG. 1A shows a manufacturing process in accordance with some embodiments of the present disclosure.

FIG. 1B shows a schematic sectional view of a light-emitting diode array structure after implementing the step S00 of the manufacturing process shown in FIG. 1A.

FIG. 1C shows a schematic sectional view of a light-emitting diode array structure after implementing the step S02 of the manufacturing process shown in FIG. 1A.

FIG. 1D shows a schematic sectional view of a light-emitting diode array structure after implementing the step S04 of the manufacturing process shown in FIG. 1A.

FIG. 1E shows a schematic sectional view of a light-emitting diode array structure after implementing the step S06 of the manufacturing process shown in FIG. 1A.

FIG. 1F shows a schematic sectional view of a light-emitting diode array structure after implementing the step S08 of the manufacturing process shown in FIG. 1A.

FIG. 2A shows a manufacturing process in accordance with some embodiments of the present disclosure.

FIG. 2B shows a schematic sectional view of a light-emitting diode array structure after implementing the step S20 of the manufacturing process shown in FIG. 2A.

FIG. 2C shows a schematic sectional view of a light-emitting diode array structure after implementing the step S22 of the manufacturing process shown in FIG. 2A.

FIG. 2D shows a schematic sectional view of a light-emitting diode array structure after implementing the step S24 of the manufacturing process shown in FIG. 2A.

FIG. 2E shows a schematic sectional view of a light-emitting diode array structure after implementing the step S26 of the manufacturing process shown in FIG. 2A.

FIG. 3 shows the steps for transferring a group from a carrier to another carrier.

FIG. 4 shows the steps for trimming and sorting.

FIG. 5 shows the steps for filling vacancies of a carrier.

FIG. 6 shows the steps for filling a receiving group with a providing group.

FIG. 7 shows an apparatus for transferring electronic devices of some embodiments of the present disclosure.

FIG. 8A shows the steps for trimming and sorting by using an apparatus for transferring electronic devices.

FIG. 8B shows the steps for filling vacancies of a carrier by using an apparatus for transferring electronic devices.

FIG. 9 shows an apparatus for transferring electronic devices with a galvo scanning system.

FIG. 10 shows the steps for filling vacancies of a carrier by using an apparatus for transferring electronic devices.

FIG. 11 shows a filling process of a light-emitting diode array structure.

FIG. 12 shows the steps for transferring light-emitting diode chips from a providing carrier to a receiving carrier by using a complementary group.

FIG. 13 shows an apparatus for transferring electronic devices of some embodiments of the present disclosure.

FIG. 14 shows the steps for merging a flawed group and a complementary group.

FIG. 15 shows a schematic sectional view of a light-emitting diode array structure after implementing a filling process.

### DETAILED DESCRIPTION OF PREFERRED EMBODIMENTS

The embodiments of the present disclosure will be described in detail below with reference to the drawings so that those skilled in the art can fully understand the spirit of the present disclosure. In the descriptions of the specification, some identical symbols indicate devices having the same or similar structure, function, or principle. For the sake of brevity, devices indicated by the same symbols will not be described repeatedly.

Although the present disclosure takes light-emitting diode (LED) chips as an example, it is not limited thereto and may also be applied to other types of electronic devices or non-electronic devices. The electronic devices may be, such as LED packages, laser packages, or integrated circuit devices. The non-electronic devices may be, such as wavelength conversion units (phosphor blocks, quantum dot blocks), optical devices, or metal laminates.

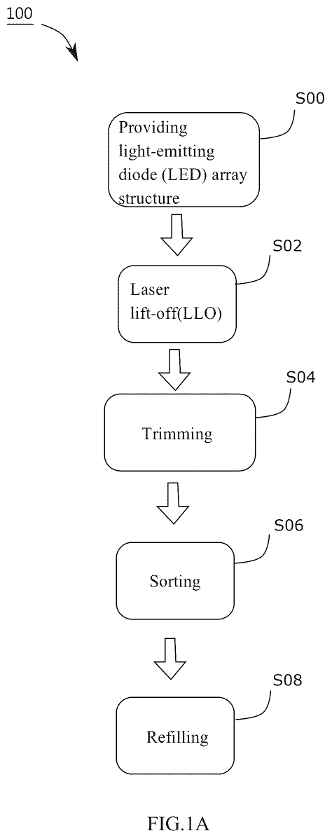

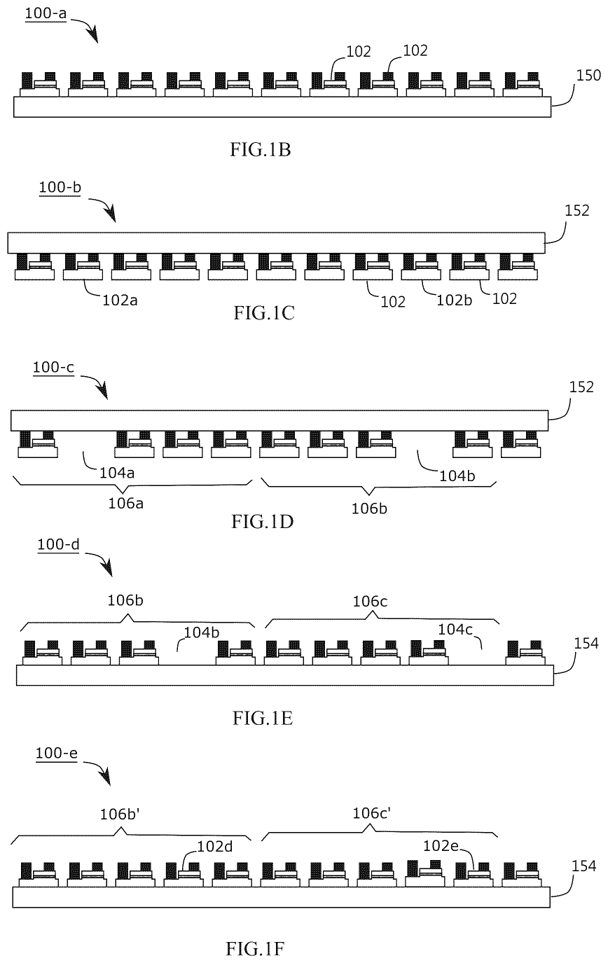

FIG. 1A shows a manufacturing process 100 in accordance with some embodiments of the present disclosure, and FIG. 1B to FIG. 1F show schematic sectional views of light-emitting diode array structures after implementing multiple steps S00 to S08 of the manufacturing process 100. The manufacturing process 100 can be used for removing bad LED chips and filling their positions with specification-qualified LED chips.

Referring to FIGS. 1A and 1B, in step S00, a light-emitting diode array structure 100-a is provided. Multiple LED chips 102 are arranged in an N×M matrix on a substrate 150, where N and M are positive integers greater than 2. For example, the substrate 150 is a structure including materials such as sapphire, silicon, or gallium arsenide (GaAs) and used for epitaxial growth. The LED chips 102 are formed on the substrate 150 by semiconductor processes such as epitaxy, deposition, photolithography, and etching. The structure shown in FIG. 1B may be referred to as chip on wafer (COW).

Then, through the laser lift-off (LLO) process in step S02 shown in FIG. 1A, the LED chips 102 are transferred from the substrate 150 to a carrier 152, thereby forming a light-emitting diode array structure 100-b shown in FIG. 1C. The carrier 152 may be a temporary carrier on which an optional adhesive layer (not shown) is disposed for carrying the LED chips 102. The structure shown in FIG. 1C may be referred to as chip on carrier (COC). In some embodiments, as shown in FIG. 1C, the LED chips 102 on the carrier 152 include two bad chips 102a and 102b. The bad chip may be, for example, an LED chip 102 whose optoelectronic characteristics do not meet specifications, and the bad chip can be detected on the substrate 150 or the carrier 152 by using testing methods such as photo luminescence (PL) and/or electro luminescence (EL).

Next, through the trimming process in step S04 shown in FIG. 1A, the bad chips 102a and 102b arranged on the carrier 152 are removed, leaving vacancies 104a and 104b at the corresponding positions on the carrier 152, thereby forming a light-emitting diode array structure 100-c. The method for removing the bad chips 102a and 102b may be a laser ablation process, where a laser is used to irradiate and vaporize the adhesive layer (not shown) between the bad chips 102a/102b and the carrier 152 by using a laser, thereby separating the bad chips 102a and 102b from the carrier 152. In another embodiment, the bad chips 102a and 102b can be directly removed by the laser. In some embodiments, the material of the adhesive layer may be organic adhesive materials with highly absorbent, such as polymethyl methacrylate (PMMA), polyphenylene ether (PPE), polyimide (PI), and epoxy.

As shown in FIG. 1D, the carrier 152 is divided into multiple sections, and the LED chips 102 on the carrier 152 are grouped into multiple groups, where a single group corresponds to or is placed on a single section, such as groups 106a and 106b. The position of a single LED chip 102 in each group may be referred to as a chip position.

After the sorting process in step S06 shown in FIG. 1A, the groups with the same or similar optoelectronic characteristics are transferred from the carrier 152 to a carrier 154, thereby forming a light-emitting diode array structure 100-d shown in FIG. 1E. The carrier 154 may include non-epitaxial materials or a non-growth substrate, such as a ceramic substrate, a metal substrate, a glass substrate, a quartz substrate, a thermal release tape, a UV release tape, a chemical release tape, a heat-resistant tape, a blue tape, or a tape with a dynamic release layer (DRL). The structure shown in FIG. 1E may be referred to as a chip on tape (COT) product. The LED chips 102 in each group can be tested and classified by photo luminescence (PL) and/or electronic luminescence (EL) methods. In some embodiments, groups 106a and 106b on the carrier 152 are designated as different categories, such as BIN1 (e.g., an emission wavelength of 411 um) and BIN2 (e.g., with an emission wavelength of 412 um). Subsequently, by using a stamping technique, the group 106b on the carrier 152 can be transferred onto the carrier 154, and the group 106a can be transferred onto another carrier (not shown). In other words, the LED chips 102 in group 106b are collectively transferred onto the carrier 154 and the LED chips 102 in group 106a are collectively transferred onto the carrier 154. Accordingly, groups belonging to category BIN2 from the same or different carriers, are transferred onto the carrier 154. In other words, all groups on the carrier 154, such as 106b and 106c, belong to the same category (e.g. category BIN2). In some embodiments, the carrier 154 can carry multiple groups of a single category. As shown in FIG. 1E, vacancies 104b and 104c also appear on the carrier 154.

Finally, through the refilling process in step S08 shown in FIG. 1A, the vacancies of the carrier 154 are filled with LED chips 102d and 102e, thereby forming a light-emitting diode array structure 100-e with groups 106b′ and 106c′ as shown in FIG. 1F. That is, the groups 106b′ and 106c′ have no vacancies. The LED chips 102d and 102e may come from another carrier (hereinafter referred to as a providing carrier, not shown) and have the same or similar optoelectronic characteristics as the LED chips in the group 106b, 106c.

As shown in FIG. 1F, in some embodiments, a plurality of groups belonging to the same category. For example, the groups 106b′ and 106c′ without vacancies, are arranged on the carrier 154. Each group include a plurality of LED chips that emit light with a single color. A display includes a plurality of pixels, and each pixel includes at least three sub-pixels that can respectively emit red light, blue light, and green light. For example, three LED chips that can respectively emit red light, blue light, and green light. Generally, red, blue, and green LED chips are respectively grown on different growth substrate and subsequently transferred onto different carriers, such as the aforementioned COW, COC, and/or COT (in the present disclosure, COW, COC, and COT are all referred to as light-emitting diode array structures).

In the manufacturing process 100, the steps of trimming and refilling consume a lot of time. Since the positions of bad chips (that is, the positions where the vacancies appear) are often random, it is difficult to optimize the trimming process and/or the refilling process. For example, if it takes 0.1 second to remove one bad chip, it takes ten thousand seconds to remove one hundred thousand bad chips.

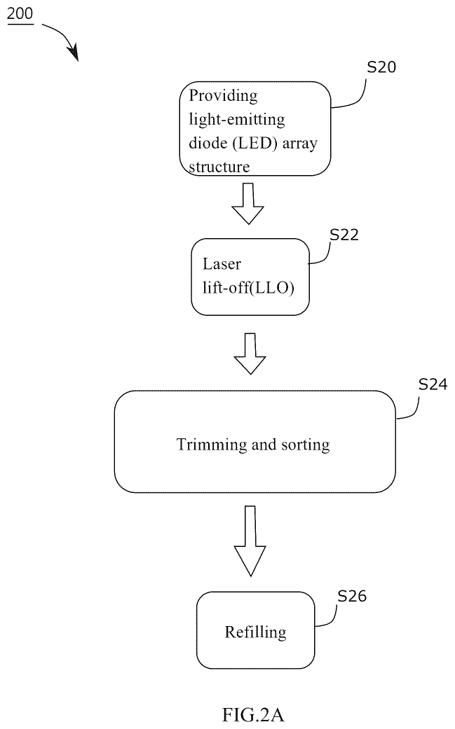

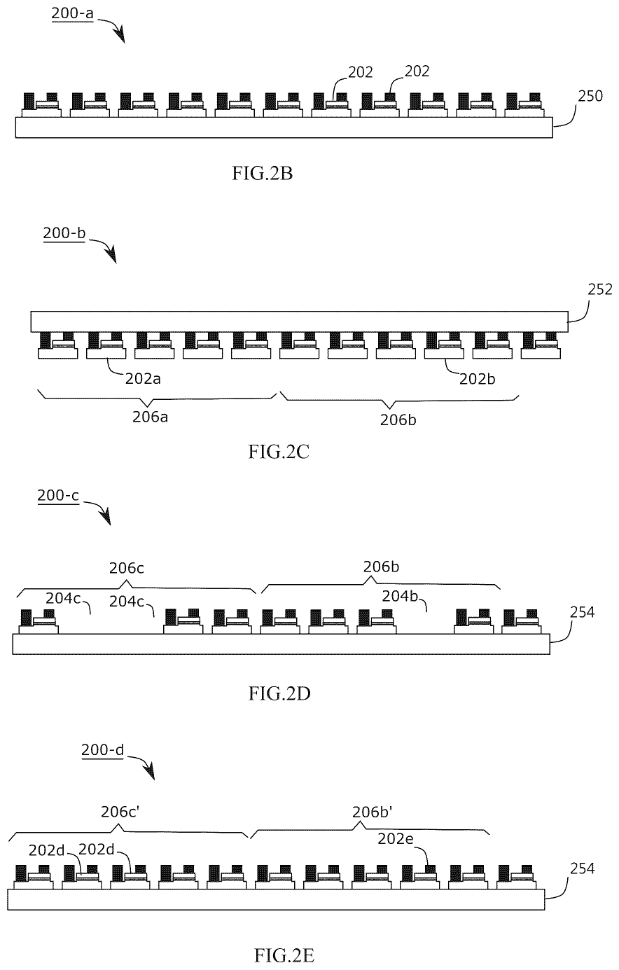

FIG. 2A shows a manufacturing process 200 according to some embodiments of the present disclosure, and FIGS. 2B to 2E respectively show schematic sectional views of light-emitting diode array structures 200-a to 200-d after implementing steps S20 to S26 of the manufacturing process 200. The manufacturing process 200 can be used for removing bad LED chips and filling their positions with specification-qualified LED chips.

Referring to FIGS. 2A and 2B, in step S20, the light-emitting diode array structure 200-a is provided. Multiple LED chips 202 are arranged in a matrix on a substrate 250. In some embodiments, the substrate 250 may be a sapphire substrate.

Then, through the laser lift-off (LLO) process in step S22 shown in FIG. 2A, the LED chips 202 are transferred from the substrate 250 to a carrier 252, thereby forming the light-emitting diode array structure 200-b shown in FIG. 2C. In some embodiments, the carrier 252 may be a temporary carrier. The LED chips 202 include two bad chips 202a and 202b, which are located in groups 206a and 206b, respectively. The groups 206a and 206b belong to BIN1 and BIN2 categories, respectively.

After the trimming and sorting process in step S24 shown in FIG. 2A, the LED chips 202 on the carrier 252 are transferred onto a carrier 254; meanwhile, the bad chips are removed and the LED chips 202 that meet the specifications are sorted (hereinafter referred to as a patterning transfer process), thereby forming the light-emitting diode array structure 200-c shown in FIG. 2D. Specifically, on the carrier 252, the groups 206b and 206c belonging to the same category, such as BIN2, are transferred onto the carrier 254. However, in the transferring step, the bad chips 202a and 202b are not transferred onto the carrier 254 and remain on the carrier 252. The groups (not shown) belonging to another category, such as BIN1, are transferred onto another carrier (not shown). As shown in FIG. 2D, in some embodiments, the bad chips 202b and 202c are not transferred onto the carrier 254, a vacancy 204b appears in the group 206b, and two vacancies 204c appear in the group 206c. The number of bad chips mentioned above is for illustrative purpose only and does not limit the scope of the present embodiment.

Finally, through the refilling process in step S26 shown in FIG. 2A, the vacancies of the carrier 254 are filled with LED chips 202d and 202e, thereby forming the light-emitting diode array structure 200-d with groups 206b′ and 206c′ as shown in FIG. 2E. That is, the groups 206b′ and 206c′ have no vacancies. Compared to the manufacturing process 100, the manufacturing process 200 combines the trimming and sorting steps into a single step, making the process more simplified.

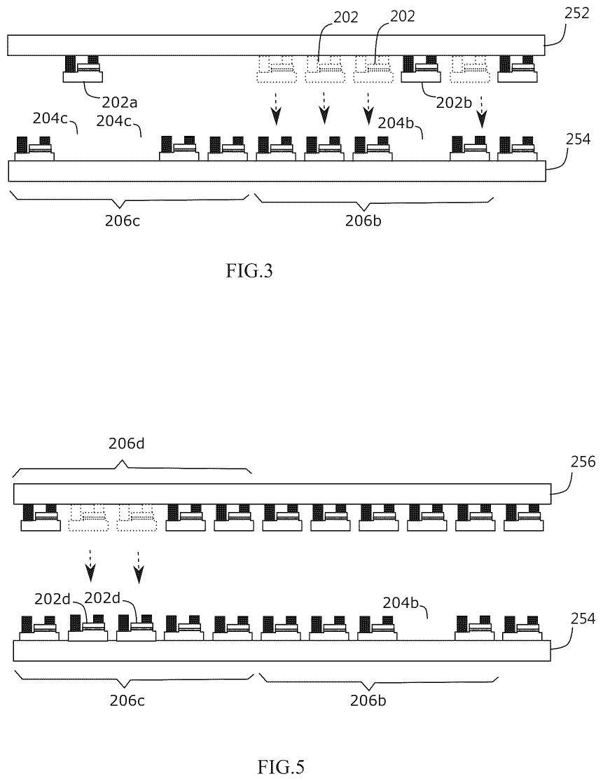

FIG. 3 shows the patterning transfer process of the step S24 in accordance with another embodiment of the present disclosure. As shown in FIG. 3, in some embodiments, four LED chips 202 to be transferred in the group 206b are transferred from the carrier 252 to the carrier 254, and the bad chip 202b remains on the carrier 252. Specifically, by irradiating the four LED chips 202 to be transferred in group 206b (also referred to as selected electronic devices) with a patterned light such as patterned laser, the four LED chips 202 to be transferred are collectively separated from the carrier 252 and transferred onto the carrier 254. Since the bad chip 202b is not selected and is not irradiated by the light, it remains on the carrier 252 and is not transferred onto the carrier 254. After the transferring step, a vacancy 204b appears in the group 206b, and the position of the vacancy 204b on the carrier 254 corresponds to the position of the bad chip 202b on the carrier 252. In FIG. 3, only the bad chip 202b remains on the carrier 252.

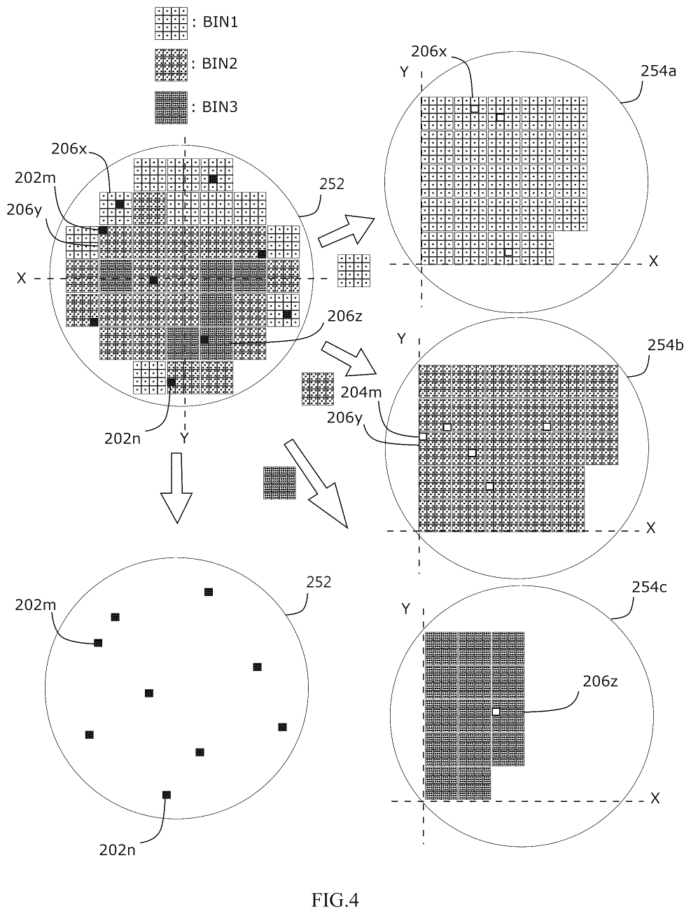

FIG. 4 shows the state of the carrier before and after the step S24 of trimming and sorting, as well as the corresponding carriers 254a, 254b, and 254c, which respectively include groups of BIN1, BIN2, and BIN3 categories.

Before the step S24 of trimming and sorting processes, there are multiple groups on the carrier 252, and each group has, such as 4×4 LED chips. In FIG. 4, in some embodiments, the groups on the carrier 252 are respectively designated as BIN1, BIN2, and BIN3 categories and some of the groups include bad chips.

The groups on the carrier 252 belonging to category BIN1 (group 206x) are transferred onto the carrier 254a; the groups on the carrier 252 belonging to category BIN2 (group 206y) are transferred onto the carrier 254b; the groups on the carrier 252 belonging to category BIN3 (group 206z) are transferred onto the carrier 254c. No bad chips are transferred. After the step S24 of trimming and sorting processes, the bad chips (bad chips 202m and 202n) remain on the carrier 252. For example, when the group 206y is transferred onto the carrier 254b, the bad chip 202m in the group 206y remains on the carrier 252. Therefore, a vacancy 204m is appeared in the group 206y on the carrier 254b.

In some embodiments, the positions of the bad chips on the carrier 252 are recorded as an integrated position, where the integrated position includes a position of the group on the carrier (referred to as a group position) and a chip position of each bad chip in the group. In FIG. 4, the carrier 252 are divided into four quadrants by X-axis and Y-axis, and the intersection of the X-axis and the Y-axis is referred to as an origin (0, 0). For example, since the group position of the group 206x is (−2, +2), it means that the group 206x is located at the upper left of the origin. In addition, the group position of the group 206y is (−2, +1), and the group position of the group 206z is (+1, −2). The chip position of each bad chip in a group may be represented by its sequence number among the bad chips in the group. For example, in FIG. 4, each group includes 4×4 LED chips, the first LED chip is located at the bottom-left corner of the group, and the second LED chip is the one to the right of the first LED chip. Accordingly, the LED chip located at the top-right corner of the group is the sixteenth one. Therefore, the integrated position of the bad chip 202m in FIG. 4 may be referred to as (−2, +1, 13), where the first two numbers indicate the group position, which means that the bad chip is located in the group 206y at the group position (−2, +1); the last number indicates a bad chip position, which means that the bad chip 202m is the thirteenth LED chip in the group 206y. Based on the aforesaid description, the integrated position of the bad chip 202n may be referred to as (0, −3, 5).

As shown in FIG. 4, on the carrier 252, the group 206y includes the bad chip 202m, where its chip position is 13. When the group 206y is transferred from the group position (−2, +1) of the carrier 252 to the group position (+0.5, +2.5) of the carrier 254b, the vacancy 204m is appeared in the group 206y on the carrier 254b. The integrated position of the vacancy 204m is (+0.5, +2.5, 13), where the chip position of the vacancy 204m corresponds to the chip position of the bad chip 202m.

FIG. 5 shows the step for transferring the LED chip 202d from a providing carrier 256 to the carrier 254. In some embodiments, the providing carrier 256 may be another temporary carrier. In another embodiment, the patterned light can be used to irradiate a selected group 206d. After the irradiation, two LED chips 202d to be transferred (the selected electronic device) are collectively separated from the providing carrier 256 and transferred onto the carrier 254 to fill the vacancies 204c. In the group 206d, the LED chips that are not irradiated by the light remain on the providing carrier 256.

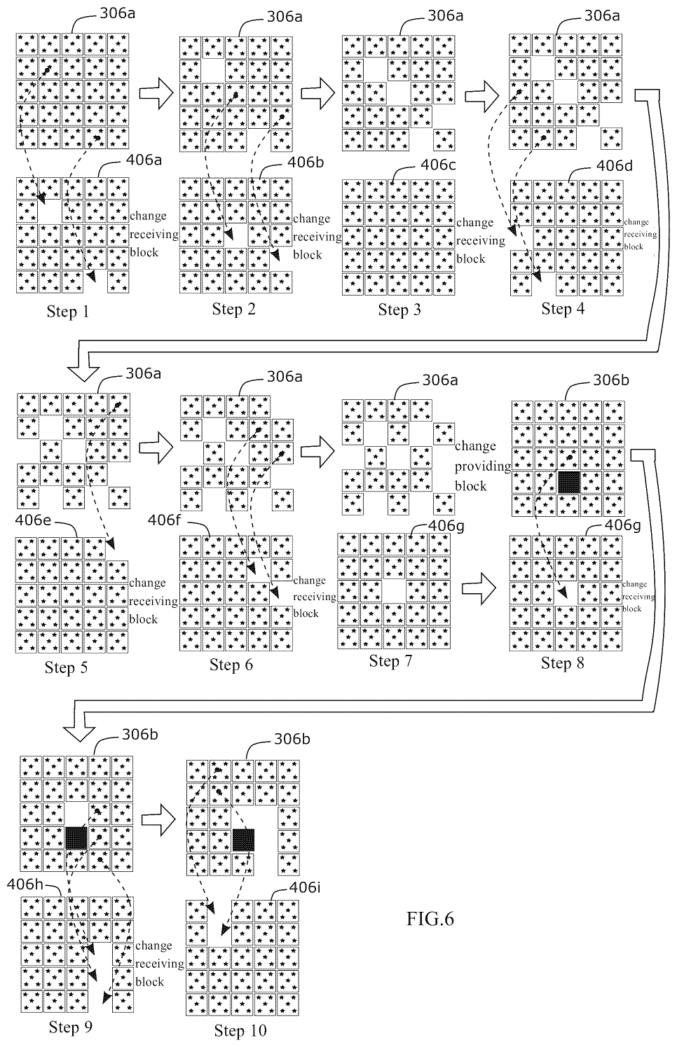

In some embodiments, the group that provides LED chips may be referred to as a providing group, and the group that receives the LED chips may be referred to as a receiving group. The LED chips in the providing group can be used for filling vacancies in the receiving group. In some embodiments, the providing group and the receiving group have the same categories of photoelectric characteristics for electronic devices. FIG. 6 shows the step for filling vacancies in receiving groups 406a to 406i with providing groups 306a and 306b. In some embodiments, both the providing group and the receiving group include LED chips arranged in the same matrix pattern and covering the same or a similar area. For example, the LED chips arranged in a 5×5 matrix. In other words, both the providing group and the receiving group include 25 LED chips, excluding any vacancies. In some embodiments, the chip position of the LED chip at the bottom-left corner of each group in FIG. 6 is designated as 1, and the chip position of the LED chip to its right is designated as 2. Accordingly, the chip position of the LED chip at the top-right corner of the group is designated as 25. It should be noted that the present disclosure is not limited to the aforementioned numbering method and can also be applied to other numbering methods, such as designating the top-left corner of the group is designated as 1 and the bottom-left corner or the bottom-right corner is designated as 25.

As shown in FIG. 6, in step 1, the LED chips in the providing group 306a are used for filling the vacancies in the receiving groups 406a. There are two vacancies in the receiving groups 406a, and their chip positions are 4 and 17, respectively. In some embodiments, vacancy positions in the receiving groups 406a (corresponding to the positions of the bad chips) can be read from a machine database through a transfer machine (not shown), and the positions with existing chips in the providing group 306a can be read from the machine database to identify the corresponding LED chips as the selected electronic devices. In the step 1, since the vacancy positions are 4 and 17, the LED chips whose chip positions are 4 and 17 in the providing group 306a become the selected electronic devices. In some embodiments, the transfer machine can simultaneously transfer the LED chips whose chip positions are 4 and 17 in the providing group 306a to fill the vacancies whose vacancy positions are 4 and 17 in the receiving group 406a. In another embodiment, the transfer machine can fill the vacancies whose vacancy positions are 4 and 17 in the receiving group 406a by transferring one chip at a time.

As shown in FIG. 6, in step 2, the vacancy positions in the receiving groups 406b are 10 and 13. In the present step, the LED chips whose chip positions are 10 and 13 in the providing group 306a are continuously to be used as the selected electronic devices, and the selected electronic devices are collectively transferred onto fill the vacancies whose vacancy positions are 10 and 13 in the receiving group 406b.

As shown in FIG. 6, in step 3, four vacancies appear in the providing group 306a, and their vacancy positions are 4, 10, 13, and 17. In the present step, there are no vacancies in the receiving group 406c so that no filling is required.

As shown in FIG. 6, steps 4 to 6 are similar to the steps 1 to 2. The providing group 306a is continuously used to sequentially fill the vacancies in the receiving groups 406d to 406f. As the refilling process proceeds, the providing group 306a continues to accumulate corresponding vacancies.

As shown in FIG. 6, in step 7, the vacancy position in the receiving group 406g is 13. Since there are no LED chips on the chip position 13 in the providing group 306a, the vacancy position in the receiving group 406g cannot be filled.

As shown in FIG. 6, in step 8, the transfer machine fills the vacancies in the receiving group 406g with the LED chips in another providing group 306b. It should be noted that there is a bad chip located at the chip position 8 in the providing group 306b, which is referred to as a vacancy by the transfer machine and cannot be transferred onto any receiving group.

Steps 9 and 10 shown in FIG. 6 can be understood by referring to the description of steps 1 to 7, and are not repeated here.

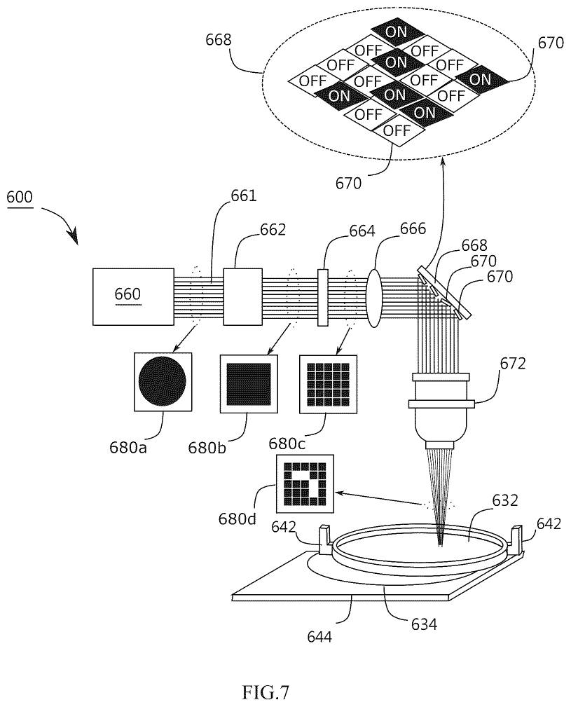

FIG. 7 shows an apparatus 600 for transferring electronic devices of some embodiments of the present disclosure, which can achieve a step for collectively transferring groups through a patterned light. The apparatus 600 includes a light source 660 (such as laser source), a shaping device 662, a photomask 664, a lens set 666, a digital micromirror devices (DMD) chip 668, an objective lens 672, and holders 642 and 644.

The light source 660 is configured to generate a light 661. When the light 661 is initially generated, its light intensity distribution 680a is approximately a circular Gaussian distribution, which may also be referred to as a Gaussian beam. The shaping device 662 adjusts the light intensity distribution 680a of the light 661 to an approximately uniform square shape, as shown by light intensity distribution 680b. The photomask 664 includes a matrix pattern to modify the light 661 into a matrix light 680c. The lens set 666 directs the matrix light 680c to the DMD chip 668. The surface of the DMD chip 668 is covered with an array of microscale mirrors 670, and each mirror can be individually controlled to tilt. Each mirror can be tilted to determine the direction of a reflected light. In other words, the DMD chip 668 provides a controllable mirror assembly including a mirror matrix, which can selectively change the direction of a portion of the light to generate the patterned light 680d. The holders 642 and 644 respectively support the providing carrier 632 and the receiving carrier 634. There are multiple LED chips on the providing carrier 632. The objective lens 672 projects the patterned light 680d onto the providing carrier 632 to collectively transfer a portion of the LED chips on the providing carrier 632 as a group to the receiving carrier 634. The holders 642 and 644 can move parallel to each other to determine the position where the transferred LED lies land on the receiving carrier 634.

As mentioned above, the apparatus 600 shown in FIG. 7 can be applied in two steps of the manufacturing process 200: trimming and sorting, and refilling.

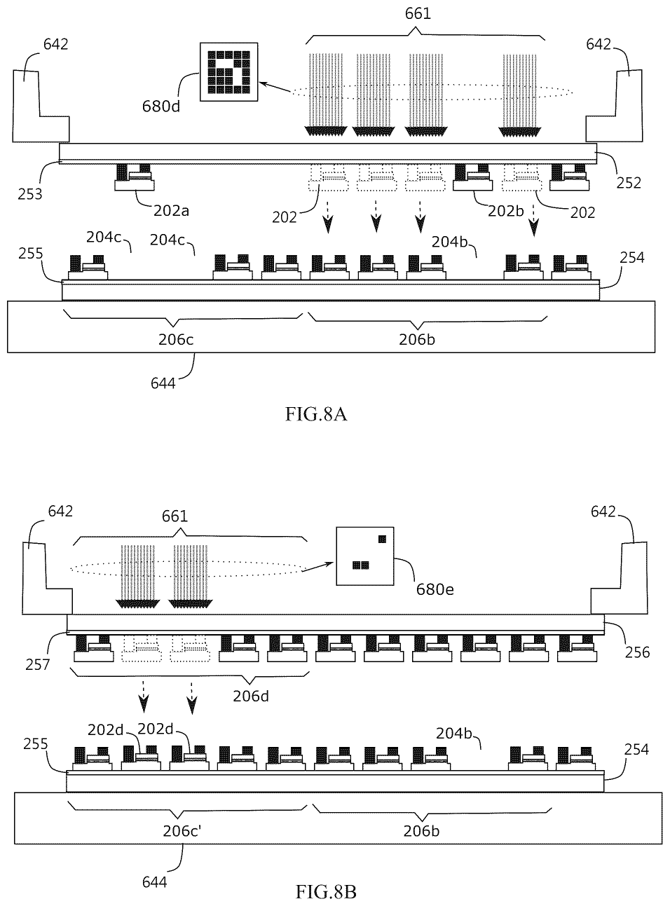

FIG. 8A shows the apparatus 600 used for the step of trimming and sorting. In FIG. 8A, the carrier 252 is to provide LED chips and is used as a providing carrier, while the carrier 254 is to receive the LED chips and is used as a receiving carrier. The holders 642 and 644 can move parallel to each other. In some embodiments, the chips on the carrier 252 are attached to an adhesive layer 253 (such as a dynamic release layer (DRL)). The dynamic release layer 253 can absorb the energy of the light 661 to generate bubbles for decreasing the contact area between the LED chips 202 and the dynamic release layer 253, thereby separating and transferring the LED chips onto the adhesive layer 255 of the carrier 254. In some embodiments, the adhesive layer 255 may be, such as a die catch material (DCM). Through the patterned light 680d, the dynamic release layer at the position of the bad chip 202b does not absorb the energy of the light 661 so that the bad chip 202b remains on the carrier 252. In FIG. 8A, the matrix formed by the mirrors 670 in the apparatus 600 corresponds to a group on the carrier 252. In some embodiments, there is a one-to-one relationship between the mirrors 670 and the LED chips in the group; that is, each mirror 670 controls whether the corresponding LED chip is detached from the carrier 252. In other embodiments, there is a many-to-one relationship between the mirrors and the LED chips in the group; that is, multiple mirrors control whether one corresponding LED chip is detached from the carrier 252.

As shown in FIGS. 7 and 8A, the patterned light 680d is determined by the bad chip 202b on the carrier 252. In other words, the apparatus 600 controls the DMD chip 668 according to the chip position of the bad chip 202b in the group 206b to generate appropriate patterned light 680d.

FIG. 8B shows the apparatus 600 used for the step of refilling. In FIG. 8B, the providing carrier 256 is a providing carrier, and the carrier 254 is a receiving carrier. The holders 642 and 644 can move parallel to each other. In some embodiments, the light 661 including a patterned light 680e is irradiated onto the providing carrier 256 to collectively separate the LED chips 202d from the providing carrier 256 and a plurality of vacancies 204c are simultaneously filled.

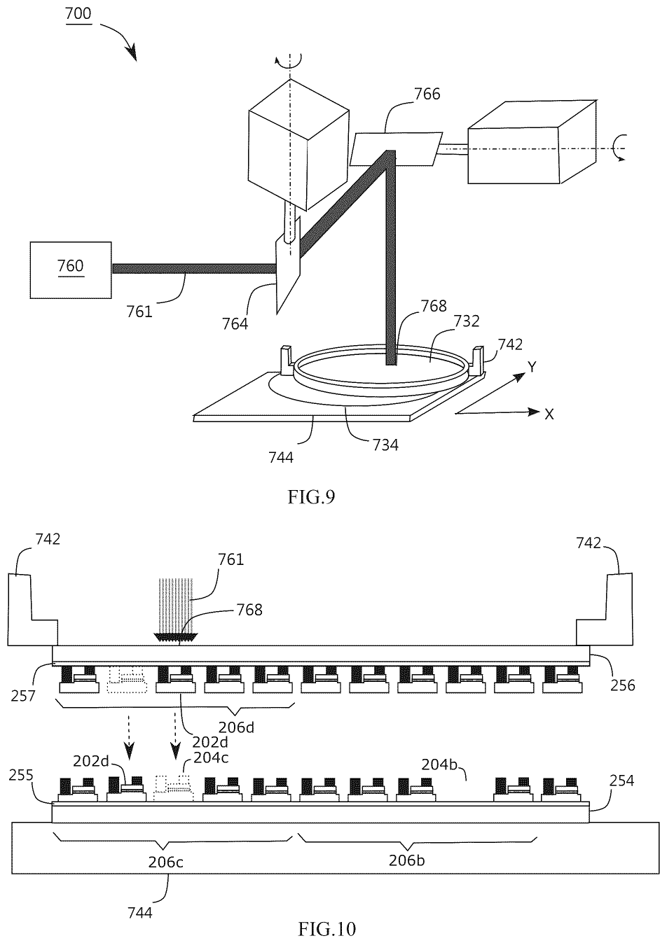

FIG. 9 shows a galvo scanning system 700 according to another embodiment of the present disclosure for achieving one-time group transfer through the patterned light. The galvo scanning system 700 can transfer LED chips from a providing carrier 732 to a receiving carrier 734. Holders 742 and 744 respectively support the providing carrier 732 and the receiving carrier 734. There are multiple LED chips on the providing carrier 732. A light source 760 (such as laser source) generates light 761 (such as laser). Galvanometers 764 and 766 are configured to reflect the light 761 so that the light 761 is irradiated onto a spot 768 on the providing carrier 732. By adjusting the reflection angles, the galvanometers 764 and 766 can respectively change the position of the spot 768 along the X-axis and the Y-axis. The LED chip located at the spot 768 can be transferred onto the receiving carrier 734.

FIG. 10 shows the galvo scanning system 700 used for the step of refilling. In FIG. 10, the carrier is used as a providing carrier 256, and the carrier 254 is used as a receiving carrier. The holders 742 and 744 can move parallel to each other. In FIG. 10, the LED chip 202d of the group 206d are transferred one by one from the providing carrier 256 to the carrier 254 to sequentially fill the plurality of vacancies 204c on the carrier 254.

In some embodiments, in the step of refilling, the holders 742 and 744 can remain still, and the position of the spot 768 is rapidly changed by controlling the galvanometers 764 and 766. Accordingly, multiple LED chip 202d in the group 206d are transferred one by one to the vacancies 204c in the group 206c.

In some embodiments, the galvo scanning system 700 can be used for the step of trimming and sorting. Please refer to FIG. 3 and FIG. 9, the LED chips 202 in the group 206b are transferred one by one to the carrier 254 through the galvo scanning system 700.

In the embodiments of the present disclosure, the patterned light is used for simultaneously finishing the steps of trimming and sorting shown in FIG. 1A, thereby accelerating the efficiency of product manufacturing. In addition, the patterned light can be used for the step of refilling, and patterned group transfer can be achieved by applying a DMD chip or a galvo scanning system.

As shown in FIG. 11, the present disclosure provides a refilling process 300′ according to some embodiments of the present disclosure. The refilling process 300′ includes steps S28 and S30. In the step 28, a complementary group is provided. In the step S30, the complementary group and a flawed group are combined. The complementary group will be described in detail later. The flawed group can refer to the light-emitting diode array structure 200-c shown in FIG. 2D. As shown in FIG. 2D, the light-emitting diode array structure 200-c includes a carrier 254 and the groups 206b and 206c on the carrier 254, where the groups 206b and 206c are flawed groups having one vacancy 204b and two vacancies 204c, respectively. In some embodiments, referring to FIG. 2A and FIG. 11, the steps S28 and S30 can follow the step S24 and replace the step S26.

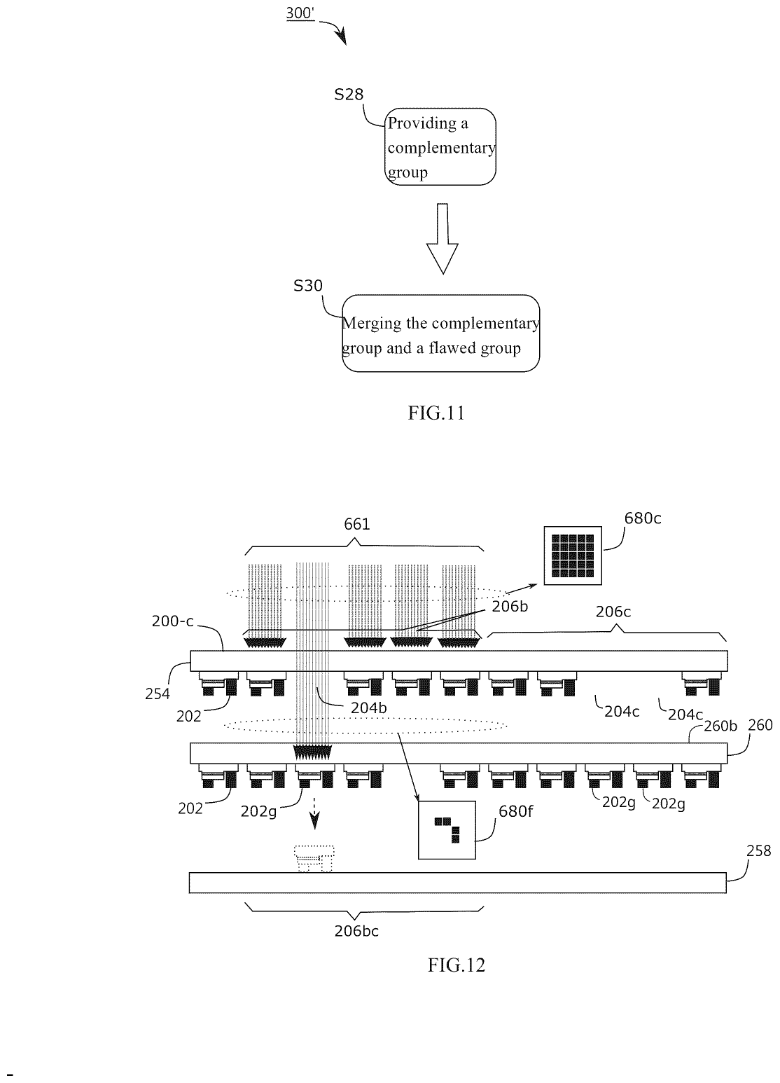

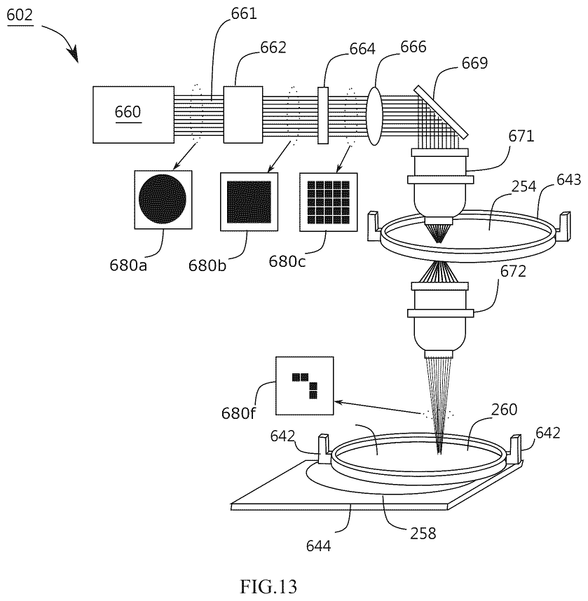

shows Referring to FIG. 12, in the step S28, the light 661, the light-emitting diode array structure 200-c (including the carrier 254 and multiple LED chips 202) shown in FIG. 2D, a providing carrier 260, the LED chip 202g on the providing carrier 260, and the receiving carrier 258 are used. Multiple LED chips 202 directly contact the providing carrier 260 or indirectly contact the providing carrier 260 through an adhesive material (now shown). Multiple LED chips 202 to be transferred are flipped on the receiving carrier 258 and do not directly contact the receiving carrier 258. After passing through the photomask 664 (referring to FIG. 13), the light 661 is converted into the matrix light 680c and then irradiates the carrier 254. In the group 206b, the LED chips block the light 661 while the vacancies 204b allow the light 661 to pass through. Therefore, in some embodiments, the light-emitting diode array structure 200-c can be referred to as a photomask. A patterned light 680f is further formed after the matrix light 680c passes through the group 206b. The patterned light 680f irradiates the LED chip 202g to be transferred (selected electronic devices) on the providing carrier 260, collectively separates the LED chip 202g to be transferred from the providing carrier 260, and transfers the LED chip 202g to the receiving carrier 258. The LED chip 202g transferred onto the receiving carrier 258 constitute a complementary group 206bc.

In some embodiments, the arrangement of the LED chip 202g in the complementary group 206bc is complementary to the arrangement of the LED chips 202 in the flawed group 206b; that is, if the LED chip 202g in the complementary group 206bc are combined with the LED chips 202 in the flawed group 206bc, a group without bad chips or vacancies can be formed. In other words, the LED chip 202g in the complementary group 206bc can completely fill the vacancy 204b in the flawed group 206b.

FIG. 13 shows an apparatus 602 used for the step S28 shown in FIG. 11. As shown in FIG. 13, the apparatus 602 includes a light source 660 (such as laser source), a shaping device 662, a photomask 664, a lens set 666, a mirror 669, objective lenses 671 and 672, and holders 642, 643, and 644. The description of the apparatus 602 can be referred to the apparatus 600 shown in FIG. 7 and the related paragraphs.

As shown in FIG. 13, the mirror 669 can change the direction of the light 661. The objective lens 671 projects the matrix light 680c onto the carrier 254 with flawed groups. The holder 643 is to carry the light-emitting diode array structure 200-c and is moveable relative to the light 661 in a two-dimensional space to make the light 661 to a specific position on the carrier 254. The matrix light 680c is further patterned by the light-emitting diode array structure 200-c into the patterned light 680f. The patterned light 680f is directed to the providing carrier 260 by the objective lens 672 and collectively transfer a plurality of LED chips 202 on the providing carrier 260 to the receiving carrier 258.

In FIGS. 12 and 13, the light 661 is configured to detach the LED chips on the providing carrier 260 from the providing carrier 260 and not to detach the LED chips on the carrier 254 from the carrier 254; that is, a corresponding flawed group cannot be affected when generating a complementary group. In some embodiments, the energy required for the light 661 to decompose the adhesive layer (not shown) on the surface of the carrier 254 is higher than the energy (the bond energy of the substrate material) required for the light to decompose the adhesive layer (not shown) on the surface of the providing carrier 260. In some embodiments, the materials of the adhesive layer may be photosensitive organic polymer, such as acrylic, polyphenylene ether (PPE), polyimide (PI), and epoxy.

In another embodiment, the step S28 shown in FIG. 11 includes two steps: replicating pattern and transferring chips. As shown in FIG. 12, in the step of replicating pattern, a photoresist layer (not shown) is formed on the surface 260b (back side) of the providing substrate 260 opposite to the surface on which the LED chips 202/202g are disposed. Then, the light-emitting diode array structure 200-c is used as a photomask to pattern the photoresist layer through a photolithography process using another light (such as laser). In other words, in the step of replicating pattern, the pattern of the group 206b (the flawed group) is replicated to the photoresist layer on the back side 260b of the providing carrier 260. In the step of transferring chips, the selected LED chip 202g on the providing carrier 260 are transferred onto the carrier 258 to generate the complementary group 206bc by using the light, with the patterned photoresist layer serving to as a photomask. During formation of the pattern, the LED chips 202 may be irradiated by the another light. Therefore, using different light sources in the step of replicating pattern and the step of transferring chips, the adhesion strength between the LED chips 202 and the carrier 254 is prevented from being weakened during the step of replicating pattern. In some embodiments, the differences between these light sources lie in their physical characteristics, such as frequency, wavelength, or pulse-width. Specifically, the physical characteristics of the light source can be adjusted according to different steps.

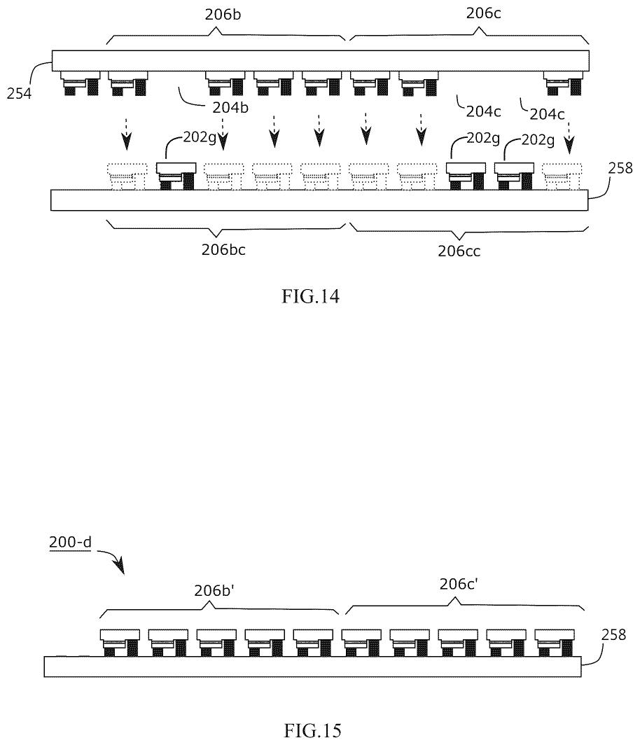

FIG. 14 shows step S30 shown in FIG. 11. The groups 206b and 206c (two flawed groups) are transferred from the carrier 254 to the receiving carrier 258. Specifically, the vacancies 204b, 204c on the groups 206b and 206c are approximately aligned with the LED chip 202g on the complementary groups 206bc and 206cc, and the chips on the groups 206b and 206c are transferred onto the receiving carrier 258 to form a light-emitting diode array structure 200-d shown in FIG. 15. The light-emitting diode array structure 200-d includes the receiving carrier 258 and complete groups 206b′ and 206c′ on the receiving carrier 258, where the complete groups 206b′ and 206c′ ideally do not include bad chips or vacancies.

Although the present disclosure has been described in considerable detail with reference to certain embodiments thereof, the disclosure is not for limiting the scope of the invention. Persons having ordinary skill in the art may make various modifications and changes without departing from the scope and spirit of the disclosure. Therefore, the scope of protection of the present disclosure shall be defined by the appended claims.

What is claimed is:

1. A method for transferring electronic devices, comprising:
providing an electronic device array structure, wherein the electronic device array structure comprises a carrier and a flawed group arranged on the carrier, and the flawed group comprises a plurality of first electronic devices and a vacancy;
providing a providing carrier and a plurality of second electronic devices arranged on the providing carrier; and
forming a light to irradiate the providing carrier by using the electronic device array structure.

2. The method according to claim 1, further comprising:
providing a receiving carrier; and
transferring a portion of the plurality of second electronic devices to the receiving carrier to form a complementary group.

3. The method according to claim 2, further comprising:
transferring the flawed group to the receiving carrier.

4. The method according to claim 1, wherein the plurality of first electronic devices and the plurality of second electronic devices comprise light-emitting diode chips.

5. The method according to claim 1, further comprising:
transferring one of the plurality of second electronic devices to the carrier to fill the vacancy.

6. The method according to claim 1, wherein the light is configured to detach one of the plurality of second electronic devices from the providing carrier.

7. The method according to claim 6, wherein the light comprises a laser.

8. The method according to claim 6, wherein the light comprises a patterned laser.

9. The method according to claim 6, wherein the providing carrier comprises an adhesive layer thereon and the light is further configured to decompose the adhesive layer on the providing carrier.

10. The method according to claim 9, wherein the material of the adhesive layer comprises photosensitive organic polymer.

11. The method according to claim 9, wherein the carrier comprises another adhesive layer thereon and the energy required for the light to decompose the another adhesive layer on the carrier is higher than the energy of the light for decomposing the adhesive layer on the providing carrier.

12. The method according to claim 3, wherein before the step of transferring the flawed group to the receiving carrier, the vacancy is approximately aligned with one of the plurality of second electronic devices on the complementary group.

13. The method according to claim 1, further comprising:
providing a photoresist layer on the providing layer.

14. The method according to claim 13, further comprising:
irradiating the electronic device array structure to pattern the photoresist layer on the providing layer.

15. An apparatus for the mass transfer process, comprising:
a first holder;
an electronic device array structure on the first holder, wherein the electronic device array structure comprises a carrier and a flawed group arranged on the carrier, and the flawed group has a plurality of first electronic devices and a vacancy;
a light source arranged on the first holder and configured to generate a light, wherein the light is converted into a patterned light through the electronic device array structure;
a second holder arranged below the first holder; and
a providing carrier on the second holder.

16. The apparatus according to claim 15, wherein the providing carrier is irradiated by the patterned light.

17. The apparatus according to claim 15, further comprising:
a third holder arranged below the second holder to support a receiving carrier.

18. The apparatus according to claim 17, further comprising a plurality of second electronic devices on the providing carrier, and the patterned light is configured to collectively transfer a portion of the plurality of second electronic devices to the receiving carrier.

19. The apparatus according to claim 18 wherein the plurality of first electronic devices and the plurality of second electronic devices are light-emitting diode chips.

20. The apparatus according to claim 15, wherein the light comprises a laser, and the patterned light comprises a patterned laser.
